(19) United States
(12) Patent Application Publication
(10) Pub. No.: US 2026/0082836 A1
(43) Pub. Date: Mar. 19, 2026

(54) METHOD AND APPARATUS FOR ETCHING A SURFACE

(71) Applicant: ASM IP Holding B.V., Almere (NL)

(72) Inventors: Matthew Surman, Helsinki (FI); Tao Xu, Helsinki (FI); Elisa Atosuo, Espoo (FI); Elina Färm, Helsinki (FI); Saima Ali, Helsinki (FI); Eva Tois, Espoo (FI)

(21) Appl. No.: 19/324,267

(22) Filed: Sep. 10, 2025

Related U.S. Application Data
(60) Provisional application No. 63/694,231, filed on Sep. 13, 2024.

(51) Int. Cl. H01L 21/3213; H01L 21/67

(52) U.S. Cl. CPC H10P 50/266; H10P 72/0421

(57) ABSTRACT

Methods and related systems for etching. Embodiments of the present disclosure comprise etching an etchable layer by executing a cyclical etching process comprising a plurality of etching cycles. Ones from the plurality of etching cycles comprises a volatilization reactant pulse that comprises exposing a substrate to a volatilization reactant. The volatilization reactant is free from metals.

### CROSS-REFERENCE TO RELATED APPLICATIONS

This application claims priority to and the benefit of U.S. Provisional Application No. 63/694,231, filed Sep. 13, 2024, the entirety of which is incorporated by reference herein.

### FIELD OF INVENTION

The present disclosure is in the field of integrated circuit processing, and particularly in the field of etching unit steps for integrated circuit manufacture.

### BACKGROUND OF THE DISCLOSURE

The patterning of metal interconnects and diffusion barriers is a crucial part of the manufacturing process. A current industry standard is the damascene process, where gaps for copper (Cu) interconnects are overfilled and extraneous material is removed with chemical mechanical polishing. This process is limited to planar processing. Patterning by direct material removal of metals most often uses wet etching methods and plasma-based reactive ion etching (RIE). The use of plasma can cause damage to the unetched layer and surrounding materials through embedding of energetic ions to the material. RIE is also characterized as an anisotropic etching method, which limits its use for etching non-line-of-sight features.

Thermal atomic layer etching is an isotropic gas phase etching method which avoids plasma damage by using thermally activated chemical reactions for the etching. It is based on self-limiting chemical modification of the surface to be etched, followed by volatilization of the modified surface layer. This enables conformal and highly controlled etching of materials.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Disclosed herein is a method of etching, comprising providing a substrate to a reaction chamber, the substrate comprising an etchable layer, the etchable layer comprising transition metal nitride; and executing a cyclical etching process comprising a plurality of etching cycles, at least one of the plurality of etching cycles comprises a volatilization reactant pulse that comprises exposing the substrate to a volatilization reactant; thereby etching the etchable layer; wherein the volatilization reactant is free from metals.

In some embodiments, the cyclical etching process is carried out thermally.

In some embodiments, the volatilization reactant comprises a halide.

In some embodiments, the volatilization reactant comprises chlorine.

In some embodiments, the volatilization reactant comprises sulfur.

In some embodiments, the volatilization reactant comprises oxygen.

In some embodiments, the volatilization reactant comprises thionyl chloride (SOCl₂).

In some embodiments, the etchable layer comprises early transition metal nitride.

In some embodiments, the etchable layer comprises TiN, MoN, or GaN.

In some embodiments, the cyclical etching process further comprises a purge step after the volatilization reactant pulse.

In some embodiments, the cyclical etching process is carried out at a temperature of at least 200° C. to at most 450° C.

Further described herein is a method for etching comprising providing a substrate to a reaction chamber, the substrate comprising an etchable layer, the etchable layer comprising transition metal; and executing a cyclical etching process comprising a plurality of etching cycles, at least one of the plurality of etching cycles comprising a nitridation reactant pulse that comprises exposing the substrate to a nitridation reactant; and at least one of the plurality of etching cycles comprising a volatilization reactant pulse that comprises exposing the substrate to a volatilization reactant; thereby etching the etchable layer; wherein the volatilization reactant is free from metals.

In some embodiments, the transition metal of the etchable layer comprises an early transition metal.

In some embodiments, the transition metal of the etchable layer comprises Ti or Mo.

In some embodiments, the etchable layer comprises Ga.

In some embodiments, the nitridation reactant comprises ammonium or tertbutyl hydrazine. In some embodiments, the nitridation reactant comprises nitrogen radicals.

In some embodiments, the nitridation reactant pulse is followed by a first purge.

In some embodiments, the volatilization reactant pulse is followed by a second purge.

Further described herein is a system comprising a reaction chamber, a substrate support, and a controller, the controller being configured for causing the system to execute a method as described herein.

In some embodiments, the system does not comprise a plasma source.

In some embodiments, there is disclosed assembly for etching a substrate comprising: one or more reaction chambers constructed and arranged to hold a substrate comprising an etchable layer, the etchable layer comprising transition metal; a volatilization reactant source vessel constructed and arranged to contain volatilization reactant; an injector system constructed and arranged to provide the volatilization reactant into the reaction chamber; and a controller operatively connected to the injector system, the nitridation reactant source vessel, and the reaction chamber, wherein the controller is configured to coordinate the operation of the assembly to perform one or more etching methods, including a method according a method as disclosed herein.

In some embodiments, there is disclosed assembly for etching a substrate comprising: one or more reaction chambers constructed and arranged to hold a substrate comprising an etchable layer, the etchable layer comprising transition metal; a nitridation reactant source vessel constructed and arranged to contain a nitridation reactant; a volatilization reactant source vessel constructed and arranged to contain volatilization reactant; an injector system constructed and arranged to provide the nitridation reactant and the volatilization reactant into the reaction chamber; and a controller operatively connected to the injector system, the nitridation reactant source vessel, the volatilization reactant source vessel, and the reaction chamber, wherein the controller is configured to coordinate the operation of the assembly to perform one or more etching methods, including a method according a method as disclosed herein.

### BRIEF DESCRIPTION OF THE DRAWING FIGURES

FIG. 1 shows embodiments of method according to the present disclosure.

FIG. 2 shows embodiments of method according to the present disclosure.

FIG. 3 shows a structure according to the present disclosure.

FIG. 4 shows an embodiment of a system according to the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

In some embodiments, terms such as “etchant reactant”, “reactant”, and “etchant” can refer generally to at least one compound that participates in etching reaction that etches a target layer on a substrate.

In some embodiments, “layer” refers to a layer continuously extending in a direction perpendicular to a thickness direction substantially without pinholes to cover an entire target or concerned surface, or simply a layer covering a target or concerned surface. In some embodiments, “layer” refers to a structure having a certain thickness formed on a surface or a synonym of film or a non-film structure. A film or layer may be constituted by a discrete single film or layer having certain characteristics or multiple films or layers, and a boundary between adjacent films or layers may or may not be clear and may be established based on physical, chemical, and/or any other characteristics, formation process or sequence, and/or functions or purposes of the adjacent films or layers.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include noble gasses such as helium, argon, and any combination thereof. In some cases, an inert gas can include nitrogen and/or hydrogen. Purge gasses can comprise inert gasses.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

In some embodiments, the term “atomic layer etching” can refer to an etching process which enables the controlled removal of material from a substrate, layer-by-layer, where the etch thickness is on the order of magnitude of a monolayer. Self-limited reaction is a key characteristic of atomic scale etching. Ideally, with atomic layer etching, adsorption and desorption steps are self-limited at a maximum rate equivalent to 1 monolayer per cycle. The total amount of material removed is determined by the number of repeated cycles. However, in some embodiments, even if one or more portions of the etch cycle is not self-limiting, controlled etching may be achieved by supplying a controlled dose of one or more of the reactants.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

Described herein are methods of etching. In some embodiments, presently disclosed methods comprise pulsed etching. In some embodiments, presently disclosed methods comprise atomic layer etching. In some embodiments, presently disclosed methods comprise self-limiting etching. An embodiment of the presently disclosed method comprises providing a substrate to a reaction chamber. The substrate comprises an etchable layer. The etchable layer comprises a transition metal nitride. A method according to an embodiment of the present disclosure comprises executing a cyclical etching process. The cyclical etching process comprises a plurality of etching cycles. At least one of the etching cycles comprises a volatilization reactant pulse that comprises exposing the substrate to a volatilization reactant. The volatilization reactant is free from metals. Thus, the etchable layer is etched.

A method according to an embodiment of the present disclosure comprises providing a substrate to a reaction chamber. The substrate comprises an etchable layer. The etchable layer comprises a transition metal. A method according to an embodiment of the present disclosure comprises executing a cyclical etching process. The cyclical etching process comprises a plurality of etching cycles. At least one of the etching cycles comprises a nitridation reactant pulse that comprises exposing the substrate to a nitridation reactant. In addition, at least one of the etching cycles comprises a volatilization reactant pulse that comprises exposing the substrate to a volatilization reactant. The volatilization reactant is free from metals. Thus, the etchable layer is etched. In some embodiments, the nitridation reactant pulse and the volatilization reactant pulse may be considered part of the same etching cycle.

The nitridation reactant nitrifies a surface of the etchable layer. The resulting nitrified surface is then etched by contacting the surface with the volatilization reactant. Doing so sequentially allows etching the etchable layer.

In some embodiments, the nitridation reactant pulse precedes the volatilization reactant pulse. In some embodiments, the volatilization reactant pulse precedes the nitridation reactant pulse.

It shall be understood that in some embodiments, the nitridation reactant pulse and the volatilization reactant pulse are at least partially non-overlapping. In some embodiments, the nitridation reactant pulse and the volatilization reactant pulse do not overlap. In some embodiments, adjacent nitridation reactant pulses and volatilization reactant pulses are separated by purges.

While the presently disclosed methods are generally described as a cyclical processes, co-flow of nitridation reactant and volatilization reactant can be done in some embodiments. In other words, in some embodiments, nitridation reactant and volatilization reactant are provided together to the reaction chamber. This can advantageously enhance throughput though such processes do not feature self-limiting steps.

In some embodiments, gas phase reactions are avoided by feeding the reactants alternately and sequentially into the reaction chamber. Vapor phase reactants are separated from each other in the reaction chamber. In some embodiments, this may be accomplished, for example, by removing excess reactants and/or reaction by-products from the reaction chamber between reactant pulses. In some embodiments, the reactants may be removed from proximity with the substrate surface with the aid of a purge gas and/or vacuum. In some embodiments, excess reactants and/or reactant byproducts are removed from the reaction space by purging, for example, with an inert gas. In some embodiments, purging comprises exposing the substrate surface to a purge gas, such as an inert gas. Because of the separation of reactants and the self-limiting nature of the reactions, less than a monolayer of material is typically removed in each etch cycle. However, in some embodiments, more than one monolayer may be removed in each cycle. In some embodiments, the reactions may not be self-limiting or saturating. In some embodiments, at least one of the phases, such as in exposure to an optional nitridation reactant, volatilization reactant or the reactants in the additional phases, the reaction, such as etching reactions, are not self-limiting or saturating. In some embodiments pulses of reactants may partially or completely overlap. For example, in some embodiments, one reactant may flow continuously into the reaction space while one or more additional reactants are provided intermittently, at desired intervals.

The etching methods disclosed herein are thermal etching processes, as opposed to plasma etching processes. Thus, plasma reactants are not used in the etch cycles. While referred to as thermal etching processes to differentiate processes that use plasma reactants, in some embodiments, the etch reactions may not require any additional thermal energy. Thus, the reactions may also be referred to as chemical etching processes herein. Thermal etching methods can be more desirable in some situations than plasma etch methods because thermal etch methods can be less damaging to the underlying substrate. Also, thermal etch methods allows for isotropic etching of non-line of sight (NLOS) features.

In some embodiments, the step of exposing the substrate to a nitridation reactant is self-limiting. In some embodiments, it may be the case that limited availability of substrate surface molecules to react with the reactant species ensures that the reaction is essentially self-limiting. In addition, the formed reaction layer itself can introduce self-limiting behavior.

In some embodiments, excess optional nitridation reactant and any reaction byproducts are removed from the proximity of the substrate surface. The optional nitridation reactant and any reaction byproducts may be removed from proximity of the substrate surface with the aid of a purge gas and/or vacuum. In some embodiments, excess reactant and/or reactant byproducts are removed from the reaction space by purging, for example, with an inert gas. In some embodiments, the substrate may be moved in order to facilitate removal of the reactant and/or reactant byproducts from the vicinity of the substrate, for example, by moving the substrate to a different reaction chamber.

In some embodiments, the volatilization reactant contacts the substrate and may convert adsorbed species to vapor phase reaction products. The reaction products include atoms of the original material, thus etching the material. Excess volatilization reactant and vapor phase reaction products are removed from the substrate surface, for example with the aid of vacuum and/or a purge gas. In some embodiments, excess volatilization reactant and reaction byproducts are removed from the reaction space by purging, for example, with an inert gas. In some embodiments, the substrate may be moved in order to facilitate removal of the reactant and/or reaction byproducts from the vicinity of the substrate, for example, by moving the substrate to a different reaction chamber.

Due to the use of vapor phase reactants, the conformality of the etching process is very good, and material can be removed evenly from all surfaces of a three-dimensional structure. In some embodiments, the conformality of etching vertically is greater than about 90% and the conformality of etching horizontally is greater than about 92%. In some embodiments, conformality of etching in vertical openings is about 50% or greater, about 75% or greater, about 85% or greater, about 90% or greater, about 95% or greater, about 98% or greater, about 99% or greater, and even up to about 100%. In some embodiments, conformality of etching in openings extending horizontally (for example, from vertical openings), is about 50% or greater, about 75% or greater, about 85% or greater, about 90% or greater, about 95% or greater, about 98% or greater, about 99% or greater, and even up to about 100%. In some embodiments, the process comprises more than two phases, more than three phases or more than four phases or more than five phases applied in cyclic manner.

In some embodiments, the substrate comprising a material to be etched, such as a semiconductor workpiece, is loaded into a reaction space or reactor. The reactor may be part of a cluster tool in which a variety of different processes in the formation of an integrated circuit are carried out. In some embodiments, a flow-type reactor is utilized. In some embodiments, a shower head type of reactor is utilized. In some embodiments, a space divided reactor is utilized. In some embodiments, a high-volume manufacturing-capable single wafer atomic layer deposition reactor is used. In other embodiments, a batch reactor comprising multiple substrates is used.

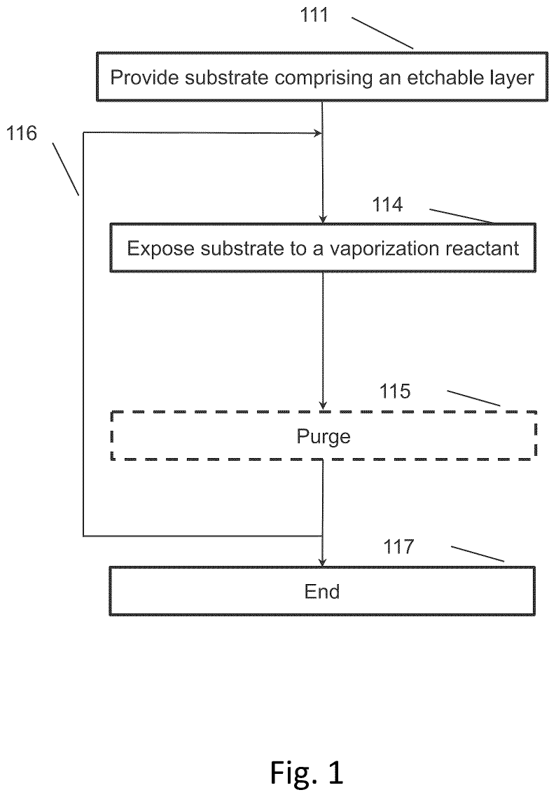

Referring to FIG. 1, described herein is an embodiment of a method according to the present disclosure. The method comprises a step 111 of providing a substrate to a reaction chamber. Then, the method comprises executing a plurality of etching cycles 116. Ones from the plurality of etching cycles comprise, in the order given, a step 114 of exposing the substrate to a volatilization reactant, and an optional purge 115. The cycles can be repeated 116. After a suitable amount of etching cycles have been carried out, the method ends.

The various process steps of the etch cycle discussed above may be sequentially repeated to remove a targeted thickness of etchable layer from the surface of the substrate. As an example, referring to the embodiment shown in FIG. 1, the method may comprise repeating steps 114 and 115 one or more (n) times to remove a targeted thickness of etchable layer from the surface of the substrate. Other steps may be inserted in the process as needed. For example, other reaction steps and/or etching steps may be performed before or after or between the n repeating cycles. The number of repeated cycles (n) is not particularly limited and depends upon the targeted etchable layer thickness that is to be removed and the etch rate of etchable layer. In some embodiments, the etchable layer is etched at a rate from about 0.1 Å to about 5 Å per etch cycle, such as at a rate from about 0.1 Å to about 3.0 Å per etch cycle, or even at a rate from about 0.3 Å to about 0.5 Å per etch cycle. In some embodiments, the etchable layer is etched at a rate from about 0.1 Å to about 3 Å per etch cycle, or at a rate from about 0.2 Å to about 1.0 Å per etch cycle, or at a rate from about 0.3 Å to about 0.5 Å per etch cycle. In some embodiments, the process is repeated until a targeted thickness of the etchable layer has been removed. In some embodiments, the process is repeated until the entire etchable layer has been removed.

In some embodiments, the etchable layer may have an initial thickness (pre-etch) of between about 0.5 nm and about 20 nm, or between about 2 nm and about 15 nm, or between about 4 nm and about 15 nm. In some embodiments, the etchable layer may have an initial thickness (pre-etch) of less than about 20 nm, or less than about 15 nm, or less than about 12 nm, or less than about 10 nm, or less than about 8 nm, or less than about 4 nm, or less than about 2 nm. In some embodiments, the number of repeated cycles (n) is between about 1 and about 5,000, between about 1 and about 2,000, between about 1 and about 1,000, between about 1 and about 500, between 1 and about 200, between about 1 and about 100, or typically between about 10 and about 1,000, typically between about 10 and about 500, typically between about 10 and about 200, typically between about 10 and about 100, or more typically between about 50 and about 1,000, or more typically between about 50 and about 500, or more typically between about 50 and about 200.

In some embodiments, the substrate may have native oxide on its surface which is removed first by exposing it to at least one pulse of a volatilization reactant. In some embodiments, the number of pulses is 5 to 100 pulses of volatilization reactant. In some embodiments, the number of pulses is 10 to 100 pulses of volatilization reactant. In some embodiments, the pulse time of pulses of volatilization reactant are 0.1 to 1 seconds. In some embodiments, there is a purge 115 after each pulse of volatilization reactant 114. In some embodiments, the purge time is 0.1 to 1 seconds.

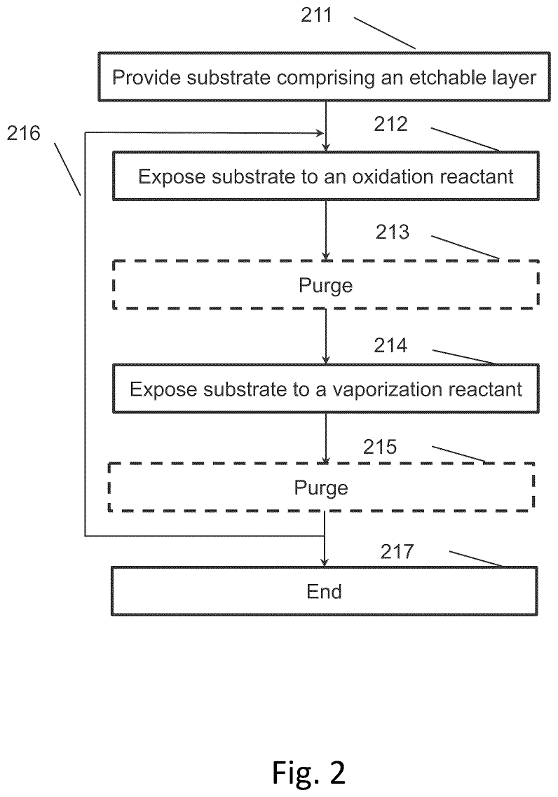

Referring to FIG. 2, described herein is an embodiment of a method according to the present disclosure. The method comprises a step 211 of providing a substrate to a reaction chamber. Then, the method comprises executing a plurality of etching cycles 216. Ones from the plurality of etching cycles comprise, in the order given, a step 212 of exposing the substrate to a nitridation reactant, an optional purge 213, a step 214 of exposing the substrate to a volatilization reactant, and another optional purge 215. Alternatively, the step of exposing the step 212 of exposing the substrate to a nitridation reactant can be preceded by the step 214 of exposing the substrate to a volatilization reactant as described herein. The cycles can be repeated 216. After a suitable amount of etching cycles have been carried out, the method ends.

The various process steps of the etch cycle discussed above may be sequentially repeated to remove a targeted thickness of etchable from the surface of the substrate. In some embodiments, referring to the embodiment shown in FIG. 2, the method may comprise repeating steps 212 and 214 one or more (n) times to remove a targeted thickness of etchable layer from the surface of the substrate. Other steps may be inserted in the process as needed. For example, other reaction steps and/or etching steps may be performed before or after or between the n repeating cycles. The number of repeated cycles (n) is not particularly limited and depends upon the targeted etchable layer thickness that is to be removed and the etch rate of etchable layer.

In some embodiments, the etchable layer is etched at a rate from about 0.1 Å to about 5 Å per etch cycle, such as at a rate from about 0.1 Å to about 2.0 Å per etch cycle, or even at a rate from about 0.3 Å to about 0.5 Å per etch cycle. In some embodiments, the etchable layer is etched at a rate from about 0.1 Å to about 3.0 Å per etch cycle, or at a rate from about 0.2 Å to about 1.0 Å per etch cycle, or at a rate from about 0.3 Å to about 0.5 Å per etch cycle. In some embodiments, the process is repeated until a targeted thickness of the etchable layer has been removed. In some embodiments, the process is repeated until the entire etchable layer has been removed. In some embodiments, the etchable layer may have an initial thickness (pre-etch) of between about 0.5 nm and about 20 nm, or between about 2 nm and about 15 nm, or between about 4 nm and about 15 nm. In some embodiments, the etchable layer may have an initial thickness (pre-etch) of less than about 20 nm, or less than about 15 nm, or less than about 12 nm, or less than about 10 nm, or less than about 8 nm, or less than about 4 nm, or less than about 2 nm. In some embodiments, the number of repeated cycles (n) is between about 1 and about 5,000, between about 1 and about 2,000, between about 1 and about 1,000, between about 1 and about 500, between 1 and about 200, between about 1 and about 100, or typically between about 10 and about 1,000, typically between about 10 and about 500, typically between about 10 and about 200, typically between about 10 and about 100, or more typically between about 50 and about 1,000, or more typically between about 50 and about 500, or more typically between about 50 and about 200.

In some embodiments, step 214 of exposing the substrate to a volatilization reactant is performed before step 212 of exposing the substrate to a nitridation reactant. In some embodiments, the substrate may have native oxide on its surface which is removed first by exposing it to at least one pulse of a volatilization reactant. In some embodiments, the number of pulses is 5 to 100 pulses of volatilization reactant. In some embodiments, the number of pulses is 10 to 100 pulses of volatilization reactant. In some embodiments, the pulse time of pulses of volatilization reactant are 0.1 to 1 seconds. In some embodiments, there is a purge 115 after each pulse of volatilization reactant 214. In some embodiments, the purge time is 0.1 to 1 seconds.

Described herein is an embodiment of a method of selectively etching. The method comprises providing a substrate to a reaction chamber. The substrate comprises an etchable layer. The etchable layer can comprise a transition metal or transition metal nitride. The substrate further comprising a second layer. The method further comprises executing an etching process that comprises sequentially exposing the substrate to an optional nitridation reactant and to a volatilization reactant. Thus, the etchable layer is etched while the second layer is not substantially etched during the cyclical etching process.

In some embodiments, the second layer comprises a dielectric material. In some embodiments, the dielectric material having a high dielectric constant (high k-value).

In some embodiments, the volatilization reactant is free from metals. In some embodiments, the volatilization reactant comprises a halide. In some embodiments, the halide is selected from fluoride, chloride, bromide and iodide.

In some embodiments, the volatilization reactant comprises at least one element selected from the group consisting of phosphorous, sulfur, nitrogen, oxygen, carbon, hydrogen and selenium. In some embodiments, the volatilization reactant comprises phosphorous or sulfur.

In some embodiments, the volatilization reactant comprises thionyl chloride (SOCl₂).

In some embodiments, the nitridation reactant comprises a nitrogen reactant. A nitrogen reactant can comprise ammonia or tertbutyl hydrazine. In some embodiments, the nitridation reactant comprises nitrogen radicals. In some embodiments, the nitridation reactant further comprises hydrogen and/or argon radicals.

In some embodiments, the etchable layer comprises at least 90, 95, 98, 99, 99.5, 99.8, or 99.9 atomic percent of the metal.

In some embodiments, the etchable layer substantially consists of the metal.

In some embodiments, the metal comprises a transition metal.

In some embodiments, the etchable layer substantially consists of a transition metal nitride.

In some embodiments, the etchable layer comprises one or more of a transition metal nitride, boride, and phosphide. In some embodiments, the etchable layer comprises metallic transition metal. In some embodiments, the etchable layer comprises an etchable material that can be nitrified using a nitrogen reactant, such as a nitrogen reactant mentioned in the present disclosure.

In some embodiments, the transition metal comprises a group 3 to 7 transition metal. In some embodiments, the transition metal comprises a group 4 to 6 transition metal. In some embodiments, the transition metal comprises at least one of molybdenum or titanium. Suitably, the transition metal can form a volatile compound with the volatilization reactant. Possible volatile compounds include chlorides and oxychlorides.

In some embodiments, the cyclical etching process is carried out thermally. In other words, and in some embodiments, the cyclical etching process does not involve generating a plasma or exposing the substrate to plasma-generated species.

In some embodiments, the substrate further comprises a second layer. In some embodiments, the second layer is not substantially etched during the cyclical etching process. In some embodiments, the second layer is etched slower than the etchable layer. In some embodiments, the etchable layer is etched at least 2 times faster than the second layer. In some embodiments, the etchable layer is etched at least 5 times faster than the second layer. In some embodiments, the etchable layer is etched at least 10 times faster than the second layer. In some embodiments, the etchable layer is etched at least 20 times faster than the second layer. In some embodiments, the etchable layer is etched at least 50 times faster than the second layer. In some embodiments, the etchable layer is etched at least 100 times faster than the second layer.

In some embodiments, the second layer comprises a dielectric material. In some embodiments, the second layer comprises a material with a high dielectric constant. In some embodiments, the dielectric material is selected from the group consisting of hafnium oxide, zirconium oxide and hafnium zirconium oxide. In some embodiments, the second layer comprises a material that forms a non-volatile material when exposed to the volatilization reactant. In some embodiments, the second layer comprises a material that is substantially unreactive with the volatilization reactant. In some embodiments, the second layer comprises a material that forms a passive layer when exposed to the volatilization reactant.

A cyclical etching process according to an embodiment of the present disclosure can be carried out at any suitable temperature. In some embodiments, the cyclical etching process is carried out at a temperature of at least 250 to at most 450° C., or of at least 200 to at most 500° C.

In some embodiments, the cyclical etching process is carried out at a pressure of at least 0.01 mbar to at most 1 bar, or at a pressure of at least 0.1 mbar to at most 0.1 bar, or at a pressure of at least 1 mbar to at most 10 mbar. In some embodiments, the cyclical etching process is carried out at a pressure of 10 mbar.

In some embodiments, the volatilization reactant is stored in a reactant source comprising a heating element. In other words, and in some embodiments, the volatilization reactant can be stored in a heated source. In some embodiments, the heated source may be maintained at a temperature of at least 20° C. to at most 200° C., or of at least 60° C. to at most 150° C., or of at least 70° C. to at most 100° C., e.g. at a temperature of 80° C.

In some embodiments, the volatilization reactant pulse is followed by a first purge.

In some embodiments, the optional nitridation reactant pulse is followed by a second purge.

Purges can comprise contacting the substrate with an inert gas. Purges can be effected by alternating gas flows, or by moving the substrate through an inert gas curtain.

In some embodiments, purging can comprise subjecting the substrate to a constant flow of inert gas. During a volatilization reactant pulse, the inert gas stream can be routed through a volatilization reactant source to entrain volatilization reactant. During a nitridation reactant pulse, the inert gas stream can be routed through a nitridation reactant source to entrain nitridation reactant. During purges, the inert gas stream can bypass the reactant sources such that no reactant is entrained. Suitable inert gas streams can comprise a noble gas such as He, Ne, Ar, Xe, or Kr. In some embodiments, the inert gas stream comprises N₂.

In some embodiments, the pulse time of the nitridation reactant is 0.5 to 60 seconds, preferably 0.5 to 10 seconds, such as 1 to 4 seconds, for example 2 to 3 seconds. In some embodiments, the pulse time of the nitridation reactant is about 1 second, or about 2 seconds, or about 3 seconds.

In some embodiments, the pulse time of the volatilization reactant is 0.5 to 120 seconds, or 0.5 to 60 seconds, preferably 0.5 to 5 seconds, such as 1 to 4 seconds, for example 2 to 3 seconds. In some embodiments, the pulse time of the volatilization reactant is about 1 second, or about 2 seconds, or about 3 seconds.

In some embodiments, the purge time after the nitridation reactant is 0.5 to 60 seconds, or 0.5 to 5 seconds, such as 1 to 4 seconds, for example 2 to 3 seconds. In some embodiments, the purge time after the nitridation reactant is about 1 second, or about 2 seconds, or about 3 seconds.

In some embodiments, the purge time after the volatilization reactant is 0.5 to 60 seconds, preferably 0.5 to 10 seconds, such as 1 to 4 seconds, for example 2 to 3 seconds. In some embodiments, the purge time after the volatilization reactant is about 1 second, or about 2 seconds, or about 3 seconds.

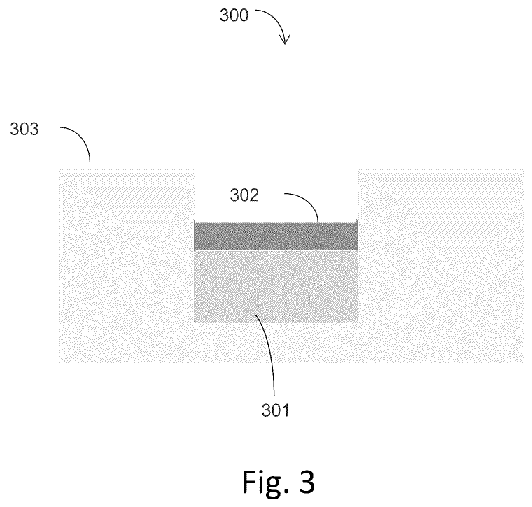

Referring to FIG. 3, described herein is structure 300. The structure 300 comprises a layer 301, a nitrified layer 302 and a second material 303. The layer 301 can comprise a substrate material as described herein. The nitrified layer 302 comprises transition metal nitride. In some embodiments, the transition metal nitride comprises molybdenum nitride. In some embodiments, the transition metal nitride comprises titanium nitride. In order to remove the nitrified layer 302, it is then exposed to a volatilization reactant and the nitrified layer 302 is removed. The layer 301 below the nidified layer 302 is not affected by the volatilization reactant. In some embodiments, the method comprises a second layer 303. In some embodiments, the second layer 303 comprises a material which is not etched. In other words, in some embodiments, the second layer is not nitrified by the nitridation reactant and it is not etched when exposed to the volatilization reactant. In some embodiments, the second layer 303 comprises a dielectric material.

Further described herein is a system that comprises a reaction chamber, a substrate support, and a controller. The controller is configured for causing the system to execute a method as described herein. In some embodiments, the system does not comprise a plasma source.

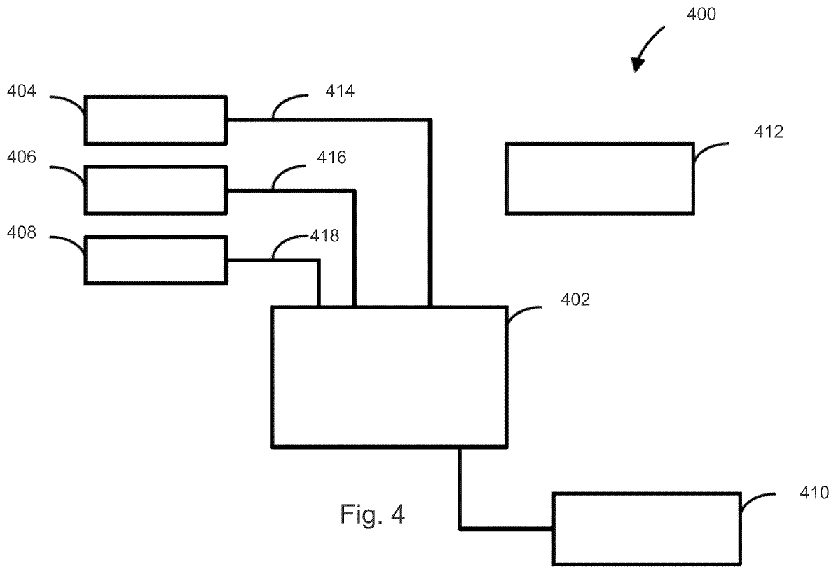

Referring to FIG. 4, further described herein is a system 400 that is constructed and arranged for carrying out an embodiment of a method as described herein.

In the illustrated example, the system 400 includes one or more reaction chambers 402, an optional nitridation reactant gas source 404, a volatilization reactant gas source 406, a purge gas source 408, an exhaust source 410, and a controller 412. In some embodiments, other gas sources can be present. In some embodiments, the system 400 can comprise a nitridation reactant gas source 404, a volatilization reactant gas source 406 source, a purge gas source 408, and further gas sources. The reaction chamber 402 can include any suitable reaction chamber. For simplicity, the system 400 is described referring only to a generic optional nitridation reactant gas source 404 and a generic volatilization reactant gas source 406.

The optional nitridation reactant gas source 404 can include a vessel and one or more precursors as described herein-alone or mixed with one or more carrier (e.g., inert) gases. The volatilization reactant gas source 406 can include a vessel and one or more reactants as described herein - alone or mixed with one or more carrier gases. The purge gas source 408 can include one or more purge gases as described herein. Although illustrated with three gas sources 404-408, the system 400 can include any suitable number of gas sources. The gas sources 404-408 can be coupled to reaction chamber 402 via lines 414-418, which can each include flow controllers, valves, heaters, and the like. The exhaust 410 can include one or more vacuum pumps.

The controller 412 includes electronic circuitry and software to selectively operate valves, manifolds, heaters, pumps and other components included in the system 400. Such circuitry and components operate to introduce precursors, reactants, and purge gases from the respective sources 404-408. The controller 412 can be configured and/or programmed to control timing of gas pulse sequences, temperature of the substrate and/or reaction chamber, pressure within the reaction chamber, and various other operations to provide proper operation of the system 400. The controller 412 can include control software to electrically or pneumatically control valves to control flow of precursors, reactants and purge gases into and out of the reaction chamber 402. The controller 412 can include modules such as a software or hardware component, e.g., a FPGA or ASIC, which performs certain tasks. A module can advantageously be configured to reside on the addressable storage medium of the control system and be configured to execute one or more processes.

Other configurations of the system 400 are possible, including different numbers and kinds of reactant sources and purge gas sources. Further, it will be appreciated that there are many arrangements of valves, conduits, precursor sources, and purge gas sources that may be used to accomplish the goal of selectively feeding gases into the reaction chamber 402. Further, as a schematic representation of a system, many components have been omitted for simplicity of illustration, and such components may include, for example, various valves, manifolds, purifiers, heaters, containers, vents, and/or bypasses.

During operation of the reactor system 400, substrates, such as semiconductor wafers (not illustrated), are transferred from, e.g., a substrate handling system to reaction chamber 402. Once substrate(s) are transferred to the reaction chamber 402, one or more gases from the gas sources 404-408, such as precursors, reactants, carrier gases, and/or purge gases, are introduced into reaction chamber 402.

Further described herein is a method of selectively depositing a layer. The method comprises providing a substrate to a reaction chamber. The substrate comprises a first surface and a second surface. The method further comprises executing a cyclical deposition process. The cyclical deposition process comprises a plurality of cycles. Ones from the plurality of cycles comprise a deposition sub step and an etching sub step. The deposition sub step comprises contacting the substrate with one or more precursors and reactants to selectively form a deposited layer on the first surface, and not or to a lesser degree on the second surface. The deposition sub step can comprise any suitable deposition technique, such as atomic layer deposition or chemical vapor deposition. The etching sub step comprises contacting the substrate with one or more etchants, conversion reactants, volatilization reactants, and/or the like. The etching sub step can comprise any suitable etch such as a continuous etch, a pulsed etch, and an atomic layer etch. The etching sub step can comprise executing an etching process according to an embodiment of the present disclosure. By sequentially and cyclically depositing and etching, selectivity can be improved, e.g. by removal of nuclei from the second surface.

Although certain embodiments and examples are disclosed herein, it will be understood by those skilled in the art that the disclosed methods and systems extend beyond the specifically disclosed embodiments and include nonobvious combinations and sub-combinations of the various processes, systems, and configurations, as well as any and all equivalents thereof. It is to be understood that the methods and/or systems described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases. Moreover, various features of the disclosure are grouped together in one or more, aspects, embodiments, and configurations for the purpose of streamlining the disclosure. The features of the aspects, embodiments, and configurations of the disclosure may be combined in alternate aspects, embodiments, and configurations other than those discussed above. The methods and systems of disclosure are not to be interpreted as reflecting an intention that the claimed disclosure requires more features than are expressly recited in each claim. Rather, as the following claims reflect, inventive aspects lie in less than all features of single foregoing disclosed aspects, embodiments, and configurations. Thus, the following claims are hereby incorporated into this Detailed Description, with each claim standing on its own as a separate preferred embodiment of the disclosure.

1. A method of etching, comprising
providing a substrate to a reaction chamber, the substrate comprising an etchable layer, the etchable layer comprising transition metal nitride; and
executing a cyclical etching process comprising a plurality of etching cycles,
at least one of the plurality of etching cycles comprises a volatilization reactant pulse that comprises exposing the substrate to a volatilization reactant;
thereby etching the etchable layer;
wherein the volatilization reactant is free from metals.

2. The method according to claim 1, wherein the cyclical etching process is carried out thermally.

3. The method according to claim 1, wherein the volatilization reactant comprises a halide.

4. The method according to claim 3, wherein the volatilization reactant comprises chlorine.

5. The method according to claim 1, wherein the volatilization reactant comprises sulphur.

6. The method according to claim 1, wherein the volatilization reactant comprises oxygen.

7. The method according to claim 1, wherein the volatilization reactant comprises thionyl chloride (SOCl₂).

8. The method according to claim 1, wherein the etchable layer comprises early transition metal nitride.

9. The method according to claim 1, wherein the etchable layer comprises GaN, TiN or MoN.

10. The method according to claim 1, wherein the cyclical etching process further comprises a purge step after the volatilization reactant pulse.

11. The method according to claim 1, wherein the cyclical etching process is carried out at a temperature of at least 200° C. to at most 450° C.

12. A method of etching, the method comprising:
providing a substrate to a reaction chamber, the substrate comprising an etchable layer, the etchable layer comprising transition metal; and
executing a cyclical etching process comprising a plurality of etching cycles,
at least one of the plurality of etching cycles comprising a nitridation reactant pulse that comprises exposing the substrate to a nitridation reactant; and
at least one of the plurality of etching cycles comprising a volatilization reactant pulse that comprises exposing the substrate to a volatilization reactant;
thereby etching the etchable layer;
wherein the volatilization reactant is free from metals.

13. The method according to claim 12, wherein the transition metal comprises an early transition metal.

14. The method according to claim 12, wherein the transition metal comprises Ti or Mo.

15. The method according to claim 12, wherein the nitridation reactant comprises ammonium or tertbutyl hydrazine.

16. The method according to claim 12, wherein the nitridation reactant comprises nitrogen radicals.

17. The method according to claim 12, wherein the nitridation reactant pulse is followed by a by a first purge.

18. The method according to claim 17, wherein the volatilization reactant pulse is followed by a second purge.

19. A system comprising a reaction chamber, a substrate support, and a controller, the controller being configured for causing the system to execute a method according to claim 1.

20. The system according to claim 19, wherein the system does not comprise a plasma source.
